(19) United States
(12) Patent Application Publication
(10) Pub. No.: US 2026/0231516 A1
(43) Pub. Date: Aug. 6, 2026

(54) INTEGRATED CIRCUIT DEVICE

(71) Applicant: Samsung Electronics Co., Ltd., Suwon-si (KR)

(72) Inventors: Seunghwan LEE, Suwon-si (KR); Ahyoung KIM, Suwon-si (KR); Yonghee PARK, Suwon-si (KR); Takeshi OKAGAKI, Suwon-si (KR); Jeesoo CHANG, Suwon-si (KR)

(73) Assignee: Samsung Electronics Co., Ltd., Suwon-si (KR)

(21) Appl. No.: 19/280,947

(22) Filed: Jul. 25, 2025

(30) Foreign Application Priority Data
Feb. 5, 2025 (KR) 10-2025-0014609

(51) Int. Cl. H10D 84/83; H01L 23/522; H01L 23/528; H10D 30/00; H10D 30/01; H10D 30/43; H10D 62/10; H10D 62/13; H10D 64/23; H10D 84/01

(52) U.S. Cl. CPC H10D 84/833; H10D 30/43; H10D 30/502; H10D 62/121; H10D 62/151; H10D 64/256; H10D 84/83125; H10W 20/42; H10W 20/435; H10D 30/014; H10D 30/0191; H10D 84/013; H10D 84/0149

(57) ABSTRACT

Provided is an integrated circuit device including a substrate, an insulating pillar extending in a first direction intersecting one surface of the substrate, a first source/drain area at one side of the insulating pillar in a second direction intersecting the first direction, a second source/drain area at another side of the insulating pillar and spaced apart from the first source/drain area in the second direction, a first source/drain contact including at least a portion being in the first source/drain area and the second source/drain area, a first silicide layer between the first source/drain area and the first source/drain contact, and a second silicide layer between the second source/drain area and the first source/drain contact, wherein the first source/drain contact is connected with the insulating pillar.

### CROSS-REFERENCE TO RELATED APPLICATIONS

This application claims the benefit of and claims priority under 35 U.S.C. § 119 to Korean Patent Application No. 10-2025-0014609, filed on Feb. 5, 2025, in the Korean Intellectual Property Office, the disclosure of which is incorporated herein by reference in its entirety.

### BACKGROUND

### 1. Field

Example embodiments relate to integrated circuit devices.

### 2. Description of the Related Art

Recently, with the rapid propagation of information media, functions of a semiconductor device are developing by leaps and bounds. As for recent semiconductor products, relatively high-density integration of a product is desired or required for relatively low costs and/or relatively high quality so as to guarantee competitiveness. For the relatively high-density integration, an integrated circuit device is being scaled down.

Meanwhile, as the down-scaling of an integrated circuit device is rapidly progressing, not only faster operation speed but also higher precision in operations is desired or required to be guaranteed in the integrated circuit device. Accordingly, various studies are being conducted to provide an integrated circuit device which has a structure that may provide the optimal or improved performance and/or may improve reliability.

### SUMMARY

Some example embodiments provide integrated circuit devices with an improved degree of integration and/or improved electric reliability.

Technical aspects, objectives and/or advantages of the present disclosure are not limited to the aforementioned technical aspects, objectives and/or advantages, and other unstated technical aspects, objectives and/or advantages may be clearly understood by those who skilled in the art from descriptions below.

According to an example embodiment, an integrated circuit device may include a substrate, an insulating pillar extending in a first direction, the first direction intersecting one surface of the substrate, a first source/drain area at one side of the insulating pillar in a second direction, the second direction intersecting the first direction, a second source/drain area at another side of the insulating pillar and spaced apart from the first source/drain area in the second direction, a first source/drain contact including at least a portion being in the first source/drain area and the second source/drain area, a first silicide layer between the first source/drain area and the first source/drain contact, and a second silicide layer between the second source/drain area and the first source/drain contact, wherein the first source/drain contact is connected with the insulating pillar.

According to an example embodiment, an integrated circuit device may include a substrate, a first insulating pillar extending in a first direction, the first direction intersecting one surface of the substrate, a second insulating pillar spaced apart from the first insulating pillar in a second direction, the second direction intersecting the first direction, a first source/drain area at one side of the first insulating pillar in the second direction, a second source/drain area spaced apart from the first source/drain area in the second direction with the first insulating pillar interposed therebetween, a third source/drain area at one side of the second insulating pillar in the second direction, a fourth source/drain area spaced apart from the third source/drain area in the second direction with the second insulating pillar interposed therebetween, a first source/drain contact including a first contact area and a second contact area, the second contact area protruding from one surface of the first contact area toward the first insulating pillar, and a second source/drain contact including a third contact area and a fourth contact area, the fourth contact area protruding from one surface of the third contact area toward the second insulating pillar.

According to an example embodiment, an integrated circuit device may include a substrate, an insulating pillar extending in a first direction, the first direction intersecting one surface of the substrate, a first source/drain area at one side of the insulating pillar in a second direction, the second direction intersecting the first direction, a second source/drain area at another side of the insulating pillar and spaced apart from the first source/drain area in the second direction, a first source/drain contact including a first contact area and a second contact are, the first contact area including a portion being in the first source/drain area and the second source/drain area, the second contact area protruding from one surface of the first contact area toward the insulating pillar, a first silicide layer between the first source/drain area and the first source/drain contact, and a second silicide layer between the second source/drain area and the first source/drain contact, wherein the first source/drain contact is connected with the insulating pillar, wherein an upper surface of the first source/drain area and an upper surface of the second source/drain area face the first contact area, and wherein a side surface of the first source/drain area and a side surface of the second source/drain area face each other with the second contact area interposed therebetween.

According to an example embodiment, a manufacturing method of an integrated circuit device may include forming a stacked structure by alternatingly stacking a sacrificial film and a semiconductor layer in a first direction intersecting one surface of a substrate on the substrate, forming an insulating pillar space by etching the stacked structure, forming a pre-insulating pillar to have at least a portion arranged in the insulating pillar space and extending in the first direction, forming a pre-first source/drain area at one side of the pre-insulating pillar and a pre-second source/drain area arranged at another side of the pre-insulating pillar in a second direction intersecting the first direction, forming a first source/drain area, a second source/drain area, an insulating pillar and a source/drain contact space by etching the pre-first source/drain area, the pre-second source/drain area and the pre-insulating pillar, forming a silicide layer at an area corresponding to the first source/drain area and the second source/drain area of an edge of the source/drain contact space surrounded by the first source/drain area, the second source/drain area and the insulating pillar, and forming a source/drain contact on the silicide layer and the insulating pillar to be spaced apart from the first source/drain area and the second source/drain area.

Detailed descriptions of other example embodiments are included in the detailed description and drawings.

Effects of the present disclosure are not limited to those described above, and other unstated effects may be apparent to those of ordinary skill in the art to which the present disclosure pertains from the following description.

In other words, unstated effects of the present disclosure may also be derived by a person skilled in the art while implementing the example embodiments included in the present disclosure.

### BRIEF DESCRIPTION OF THE FIGURES

These and/or other aspects, features, and advantages of the inventive concepts of the present disclosure will become apparent and more readily appreciated from the following description of example embodiments, taken in conjunction with the accompanying drawings of which:

FIG. 1 is a layout diagram for describing an integrated circuit device according to an example embodiment;

FIG. 2 is a diagram illustrating a cross section taken along A1-A1 of FIG. 1;

FIG. 3 is a diagram illustrating a cross section taken along A2-A2 of FIG. 1;

FIG. 4 is a diagram illustrating a cross section taken along B-B of FIG. 1;

FIG. 5 to FIG. 18B are diagrams illustrating a manufacturing method of an integrated circuit device according to an example embodiment, wherein FIG. 5A, FIG. 6, FIG. 7, FIG. 8, FIG. 9, FIG. 10, FIG. 11A, FIG. 13, FIG. 14A, and FIG. 15 are diagrams illustrating a process of manufacturing a portion corresponding to a cross section taken along A1-A1, and wherein FIG. 11B, FIG. 12A, FIG. 16A, FIG. 17A, and FIG. 18A are diagrams illustrating a process of manufacturing a portion corresponding to a cross section taken along A2-A2, and wherein FIG. 5B, FIG. 11C, FIG. 12B, FIG. 14B, FIG. 16B, FIG. 17B, and FIG. 18B are diagrams illustrating a process of manufacturing a portion corresponding to a cross section taken along B-B; and

FIG. 19 is a diagram illustrating a cross section taken along A2-A2 of FIG. 1 to describe an integrated circuit device according to another example embodiment.

### DETAILED DESCRIPTION

Before describing example embodiments in detail, the words and terminologies used in the specification and claims are not to be construed as limited to common or dictionary meanings but construed as meanings and concepts coinciding with the technical idea of the present disclosure under the principle that the inventor(s) may appropriately define the concept of the terms to explain his or her own inventive concepts better. Therefore, the example embodiments described in the specification and the configurations illustrated in the drawings are no more than some example embodiments of the present disclosure and do not fully cover the technical idea (or technical concepts) of the present disclosure. Accordingly, it should be understood that there may be various equivalents and modification examples that may replace the example embodiments when this application is filed.

In the following description, a singular expression includes a plural expression unless apparently otherwise defined by context. It should be understood that terms such as “comprise or include” and “form” are intended to indicate the presence of a feature, a number, a step, an operation, an element, a component, or a combination thereof described in the specification and not intended to exclude the possibility of the presence or addition of one or more other features, numbers, steps, operations, elements, components, or combinations thereof in advance.

The terms “first” and “second” may be used to describe various elements throughout the specification; however, the elements should not be limited by the terms and the terms may be used for the purpose of distinguishing an element from the other elements. Within the inventive concepts of the present disclosure, a first element may be referred to as a second element, and similarly, the second element may also be referred to as the first element. Further, in the accompanying drawings, the shapes, sizes, and the like of elements may be exaggerated for clearer description.

In addition, expressions such as upper side, upper portion, above, lower side, lower portion, below, side surface, front surface, and rear surface are represented hereinafter with respect to a direction illustrated in a drawing and may be represented otherwise when the direction of a corresponding object changes. The shapes, sizes, and the like of elements may be exaggerated in the drawings for clearer description.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, some example embodiments according to the inventive concepts of the present disclosure will be described with reference to the accompanying drawings.

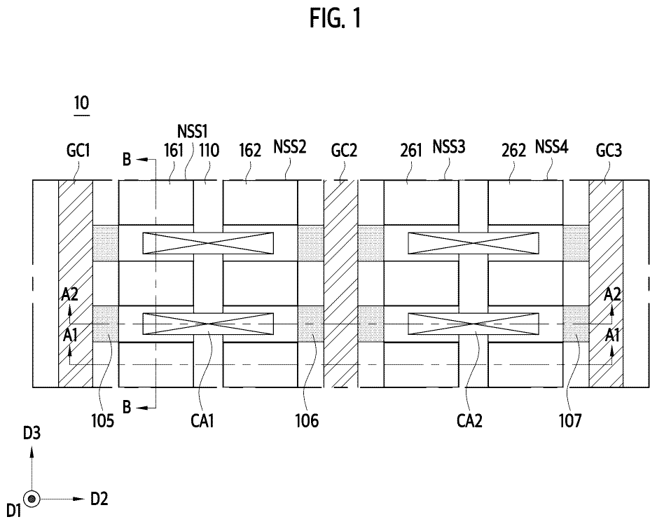

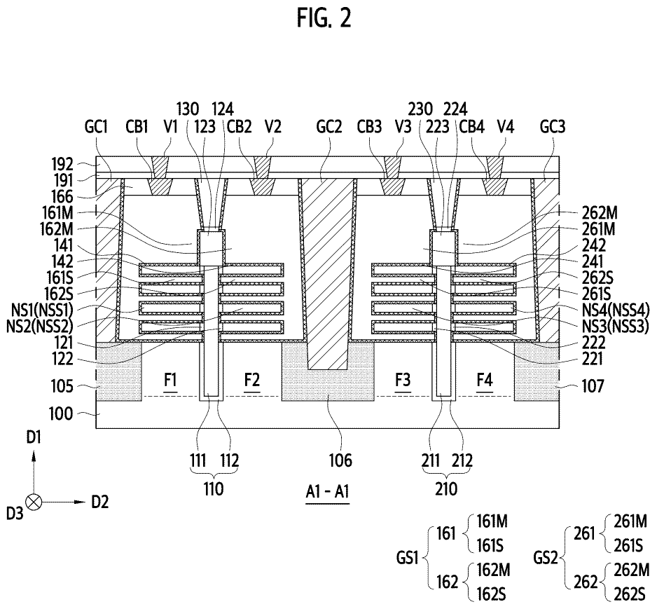

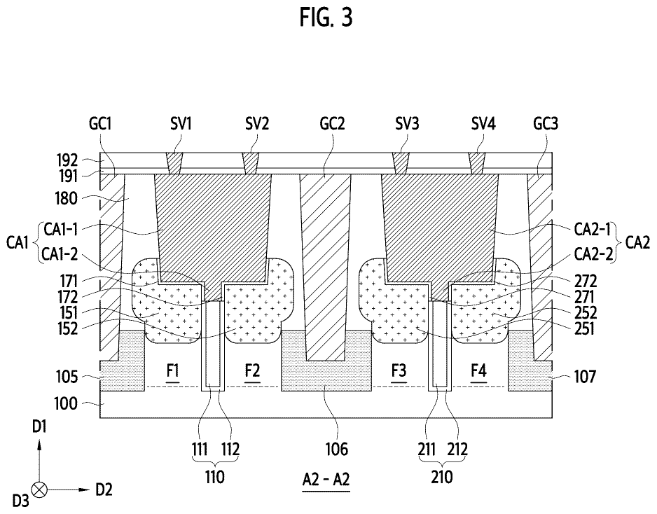

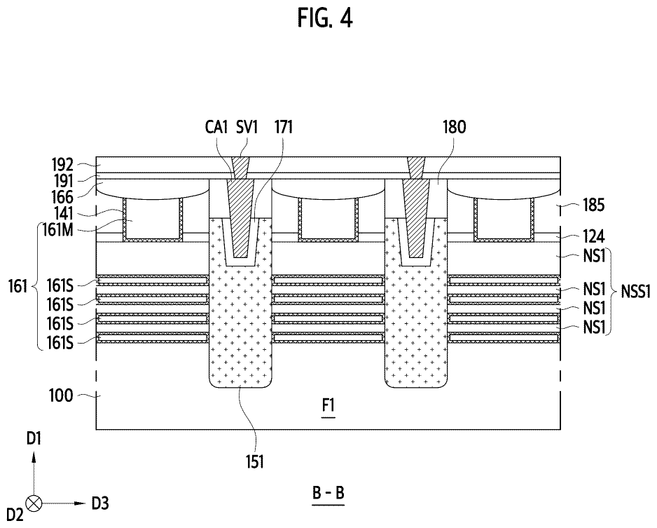

FIG. 1 is a layout diagram for describing an integrated circuit device 10 according to an example embodiment, FIG. 2 is a diagram illustrating a cross section taken along A1-A1 of FIG. 1, FIG. 3 is a diagram illustrating a cross section taken along A2-A2 of FIG. 1, and FIG. 4 is a diagram illustrating a cross section taken along B-B of FIG. 1.

Referring to FIG. 1 to FIG. 4, the integrated circuit device 10 according to some example embodiments includes a substrate 100, a first field insulating film 105, a second field insulating film 106, and a third field insulating film 107, a first insulating pillar 110, a second insulating pillar 210, a first barrier 121, a second barrier 122, a third barrier 221, and a fourth barrier 222, a first insulating cap 123, a second insulating cap 223, a first upper insulating pillar 130, a second upper insulating pillar 230, a first gate dielectric film 141, a second gate dielectric film 142, a third gate dielectric film 241, and a fourth gate dielectric film 242, a first source/drain area 151, a second source/drain area 152, a third source/drain area 251, and a fourth source/drain area 252, a first gate line 161, a second gate line 162, a third gate line 261, and a fourth gate line 262, a first silicide layer 171, a second silicide layer 172, a third silicide layer 271, and a fourth silicide layer 272, a capping pattern 166, a first interlayer insulating film 180, a second interlayer insulating film 192, an etching stopping film 191, a first gate contact CB1 to a fourth gate contact CB4, a first via V1 to a fourth via V4, a first source/drain contact CA1, a second source/drain contact CA2, a first gate cut GC1 to a third gate cut GC3, a first nano sheet stack NSS1 to a fourth nano sheet stack NSS4, and a first source/drain via SV1 to a fourth source/drain via SV4.

According to some example embodiments, a first direction D1 may signify a direction perpendicular to one surface of the substrate 100. A second direction D2 may signify a direction intersecting the first direction D1. The second direction D2 may be in parallel with a horizontal direction of one surface of the substrate 100. A third direction D3 may signify a direction intersecting the first direction D1 and the second direction D2. The third direction D3 may be in parallel with a horizontal direction of one surface of the substrate 100. The first direction D1 and the second direction D2 may be perpendicular to each other, the second direction D2 and the third direction D3 may be perpendicular to each other, and the third direction D3 and the first direction D1 may be perpendicular to each other.

According to some example embodiments, the substrate 100 may be a silicon substrate or silicon-on-insulator (SOI). In some example embodiments, the substrate 100 may include silicon germanium, silicon germanium on insulator (SGOI), indium antimonide, a lead telluride compound, indium arsenide, indium phosphide, gallium arsenide or gallium antimonide. However, the substrate 100 is not limited thereto.

According to some example embodiments, each of a first active area F1 to a fourth active area F4 may protrude from the substrate 100 in the first direction D1. In the present disclosure, the first direction D1 may be defined as a direction intersecting each of the second direction D2 and the third direction D3, which is different from the second direction D2. Each of the first active area F1 to the fourth active area F4 may be part of the substrate 100 and may include an epi-layer grown from the substrate 100. Each of the first active area F1 to the fourth active area F4 may extend in the third direction D3. The substrate 100 may extend in the second direction D2 and/or the third direction D3.

According to some example embodiments, the first active area F1 to the fourth active area F4 may be spaced apart from each other in the second direction D2 in a sequential manner. The first active area F1, the second active area F2, the third active area F3 and the fourth active area F4 may be sequentially and parallelly arranged in the second direction D2.

According to some example embodiments, the first field insulating film 105 to the third field insulating film 107 may be arranged on the substrate 100. The first field insulating film 105 to the third field insulating film 107 may cover a side wall of the first active area F1 to a side wall of the fourth active area F4. The first field insulating film 105 to the third field insulating film 107 may include, for example, one of silicon nitride (SiN), silicon oxynitride (SiON), silicon oxide (SiO2), silicon oxycarbonitride (SiOCN) or a combination thereof, without being limited thereto.

According to some example embodiments, the first insulating pillar 110 may extend in the third direction D3 in a space between the first field insulating film 105 and the second field insulating film 106 which are adjacent to each other. For example, a lower end part of the first insulating pillar 110 is disposed between the first active area F1 and the second active area F2 to extend in the third direction D3 while simultaneously extending in the first direction D1. In other words, a lower end part of the first insulating pillar 110 is disposed between the first active area F1 and the second active area F2 and extends in the third direction D3 and in the first direction D1. One surface of the first insulating pillar 110 may be connected with the substrate 100 between the first active area F1 and the second active area F2. The first insulating pillar 110 may function as a separating film between the first active area F1 and the second active area F2. An upper end part of the first insulating pillar 110 may be disposed between the first gate line 161 and the second gate line 162, and between a first nano-sheet NS1 and a second nano-sheet NS2.

According to some example embodiments, the second insulating pillar 210 may extend in the third direction D3 in a space between the second field insulating film 106 and the third field insulating film 107 which are adjacent to each other. For example, a lower end part of the second insulating pillar 210 is disposed between the third active area F3 and the fourth active area F4 to extend in the third direction D3 while simultaneously extending in the first direction D1. In other words, a lower end part of the second insulating pillar 210 is disposed between the third active area F3 and the fourth active area F4 and extends in the third direction D3 and in the first direction D1. One surface of the second insulating pillar 210 may be connected with the substrate 100 between the third active area F3 and the fourth active area F4. The second insulating pillar 210 may function as a separating film between the third active area F3 and the fourth active area F4. An upper end part of the second insulating pillar 210 may be disposed between the third gate line 261 and the fourth gate line 262, and between a third nano-sheet NS3 and a fourth nano-sheet NS4.

According to some example embodiments, the first insulating pillar 110 may include a first filling film 111 that extends long in the first direction D1 and a first insulating liner 112 covering a side wall and a bottom surface of a lower end part of the first filling film 111. The second insulating pillar 210 may include a second filling film 211 that extends long in the first direction D1 and a second insulating liner 212 covering a side wall and a bottom surface of a lower end part of the second filling film 211. For instance, the first filling film 111, the second filling film 211, the first insulating liner 112 and the second insulating liner 212 may include at least one of SiOC, SiOCN, SiN, SiCN or a combination thereof. However, materials included in the first filling film 111, the second filling film 211, the first insulating liner 112 and the second insulating liner 212 are not limited thereto.

According to some example embodiments, on each of the first active area F1 to the fourth active area F4, a plurality of nano-sheet stacks (e.g., a first nano-sheet stack NSS1 to a fourth nano-sheet stack NSS4) may be arranged. The first nano-sheet stack NSS1 may be arranged on the first active area F1, the second nano-sheet stack NSS2 may be arranged on the second active area F2, the third nano-sheet stack NSS3 may be arranged on the third active area F3, and the fourth nano-sheet stack NSS4 may be arranged on the fourth active area F4. The first nano-sheet stack NSS1 to the fourth nano-sheet stack NSS4 may be sequentially spaced apart from each other in the second direction D2.

According to some example embodiments, the first nano-sheet stack NSS1 may include the plurality of first nano-sheets NS1 which are spaced apart from each other in the first direction D1, the second nano-sheet stack NSS2 may include the plurality of second nano-sheets NS2 which are spaced apart from each other in the first direction D1, the third nano-sheet stack NSS3 may include the plurality of third nano-sheets NS3 which are spaced apart from each other in the first direction D1, and the fourth nano-sheet stack NSS4 may include the plurality of fourth nano-sheets NS4 which are spaced apart from each other in the first direction D1. In FIG. 2, although the first nano-sheet stack NSS1 to the fourth nano-sheet stack NSS4 are illustrated as including four nano-sheets spaced apart from each other in the first direction D1, inventive concepts of the present disclosure are not limited thereto. For instance, each of the first nano-sheet stack NSS1 to the fourth nano-sheet stack NSS4 may include two, three, five or more nano-sheets which are spaced apart from each other in the first direction D1.

According to some example embodiments, the first nano-sheet NS1 may extend in an opposite direction (a direction-D2) to the second direction from the first insulating pillar 110. For example, the first nano-sheet NS1, the first barrier 121 and the first filling film 111 of the first insulating pillar 110 may be monolithically formed with each other. In other words, the first nano-sheet NS1, the first barrier 121 and the first filling film 111 of the first insulating pillar 110 may form an integral body with each other. The second nano-sheet NS2 may extend in the second direction D2 from the first insulating pillar 110. The second nano-sheet NS2, the second barrier 122 and the first filling film 111 of the first insulating pillar 110 may be monolithically formed with each other. In other words, the second nano-sheet NS2, the second barrier 122 and the first filling film 111 of the first insulating pillar 110 may form an integral body with each other. The third nano-sheet NS3 may extend in the opposite direction (the direction-D2) to the second direction from the second insulating pillar 210. For example, the third nano-sheet NS3, the third barrier 221 and the second filling film 211 of the second insulating pillar 210 may be monolithically formed with each other. In other words, the third nano-sheet NS3, the third barrier 221 and the second filling film 211 of the second insulating pillar 210 may form an integral body with each other. The fourth nano-sheet NS4 may extend in the second direction D2 from the second insulating pillar 210. The fourth nano-sheet NS4, the fourth barrier 222 and the second filling film 211 of the second insulating pillar 210 may be monolithically formed with each other. In other words, the fourth nano-sheet NS4, the fourth barrier 222 and the second filling film 211 of the second insulating pillar 210 may form an integral body with each other.

According to some example embodiments, the first barrier 121 may be disposed between the first nano-sheet NS1 and the first filling film 111, and the second barrier 122 may be disposed between the second nano-sheet NS2 and the first filling film 111. The third barrier 221 may be disposed between the third nano-sheet NS3 and the second filling film 211, and the fourth barrier 222 may be disposed between the fourth nano-sheet NS4 and the second filling film 211.

According to some example embodiments, the first insulating cap 123 may be arranged on an upper surface of a portion of the first insulating pillar 110, which is disposed between the first nano-sheet stack NSS1 and the second nano-sheet stack NSS2. The first insulating cap 123 may be arranged to be in contact with a portion of an upper surface of the first insulating pillar 110. The first insulating cap 123 may not be arranged on an upper surface of a portion of the first insulating pillar 110 disposed between the first source/drain area 151 and the second source/drain area 152.

According to some example embodiments, the first source/drain contact CA1 may be arranged on an upper surface of a portion of the first insulating pillar 110, which is disposed between the first source/drain area 151 and the second source/drain area 152.

According to some example embodiments, the second insulating cap 223 may be arranged on an upper surface of a portion of the second insulating pillar 210, which is disposed between the third nano-sheet stack NSS3 and the fourth nano-sheet stack NSS4. The second insulating cap 223 may be arranged to be in contact with a portion of an upper surface of the second insulating pillar 210. The second insulating cap 223 may not be arranged on an upper surface of a portion of the second insulating pillar 210 disposed between the third source/drain area 251 and the fourth source/drain area 252.

According to some example embodiments, the second source/drain contact CA2 may be arranged on an upper surface of a portion of the second insulating pillar 210, which is disposed between the third source/drain area 251 and the fourth source/drain area 252.

According to some example embodiments, each of the first gate line 161, the second gate line 162, the third gate line 261, and the fourth gate line 262 may extend in the third direction D3 on the active areas (e.g., the first active area F1 to the fourth active area F4), respectively. Each of the first gate line 161, the second gate line 162, the third gate line 261, and the fourth gate line 262 may surround a corresponding one of the first nano-sheet stack NSS1 to the fourth nano-sheet stack NSS4. For instance, the first gate line 161 and the second gate line 162 may constitute a first gate structure GS1, and the third gate line 261 and the fourth gate line 262 may constitute a second gate structure GS2.

According to some example embodiments, the plurality of gate lines (e.g., the first gate line 161, the second gate line 162, the third gate line 261, and the fourth gate line 262) may include main gate parts (e.g., a first main gate part 161M, a second main gate part 162M, a third main gate part 261M, and a fourth main gate part 262M) which cover upper surfaces of the first nano-sheet stack NSS1 to the fourth nano-sheet stack NSS4, respectively, and a plurality of sub-gate parts (e.g., a first sub-gate part 161S, a second sub-gate part 162S, a third sub-gate part 261S, and a fourth sub-gate part 262S) which are connected with the main gate parts (e.g., the first main gate part 161M, the second main gate part 162M, the third main gate part 261M, and the fourth main gate part 262M), respectively, and are formed at spaces between the plurality of nano-sheets (e.g., the first nano-sheet NS1 to the fourth nano-sheet NS4) and between each of the active areas (e.g., the first active area F1 to the fourth active area F4) and a corresponding one of the plurality of nano-sheets (e.g., the first nano-sheet NS1 to the fourth nano-sheet NS4).

According to some example embodiments, the first gate line 161, the second gate line 162, the third gate line 261, and the fourth gate line 262 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), Palladium (Pd), Iridium (Ir), Osmium (Os), Silver (Ag), Gold (Au), Zinc (Zn), Vanadium (V), or a combination thereof. Each of the first gate line 161, the second gate line 162, the third gate line 261, and the fourth gate line 262 may include conductive metal oxide, conductive metal oxynitride or the like and may include an oxidized state of the above-described materials.

According to some example embodiments, the first source/drain area 151 may be disposed on at least one side of the first gate line 161 in the third direction D3 on the first active area F1. The first source/drain area 151 may be disposed at one side of the first insulating pillar 110 in the second direction D2. For instance, the first source/drain area 151 may be provided in plural by being spaced apart in the third direction D3, and the pair of first source/drain areas 151 may be disposed at both sides of the first gate line 161 along the third direction D3 on the first active area F1. The first source/drain area 151 may be disposed between the plurality of first nano-sheet stacks NSS1 parallelly arranged along the third direction D3. The first source/drain area 151 may be in contact with each of the plurality of first nano-sheets NS1.

According to some example embodiments, the second source/drain area 152 may be disposed on at least one side of the second gate line 162 in the third direction D3 on the second active area F2. The second source/drain area 152 may be arranged at the other side of the first insulating pillar 110 in the second direction D2. For instance, the second source/drain area 152 may be provided in plural by being spaced apart along the third direction D3, and the pair of second source/drain areas 152 may be disposed at both sides of the second gate line 162 along the third direction D3 on the second active area F2. The second source/drain area 152 may be disposed between the plurality of second nano-sheet stacks NSS2 parallelly arranged along the third direction D3. The second source/drain area 152 may be in contact with each of the plurality of second nano-sheets NS2.

According to some example embodiments, the first source/drain area 151 and the second source/drain area 152 may be a p-type source/drain area doped with p-type impurities. For instance, the p-type impurities may include at least one of elements of boron (B), aluminum (Al), gallium (Ga) or Indium (In). The plurality of first source/drain areas 151, the first gate line 161 and the first nano-sheet stack NSS1 may constitute a PMOS transistor. The plurality of second source/drain areas 152, the second gate line 162 and the second nano-sheet stack NSS2 may constitute a PMOS transistor.

According to some example embodiments, the third source/drain area 251 may be disposed on at least one side of the third gate line 261 in the third direction D3 on the third active area F3. The third source/drain area 251 may be disposed at one side of the second insulating pillar 210 in the second direction D2. For instance, the third source/drain area 251 may be provided in plural by being spaced apart along the third direction D3, and the pair of third source/drain areas 251 may be disposed at both sides of the third gate line 261 along the third direction D3 on the third active area F3. The third source/drain area 251 may be disposed between the plurality of third nano-sheet stacks NSS3 parallelly arranged in the third direction D3. The third source/drain area 251 may be in contact with each of the plurality of third nano-sheets NS3.

According to some example embodiments, the fourth source/drain area 252 may be disposed on at least one side of the fourth gate line 262 in the third direction D3 on the fourth active area F4. The fourth source/drain area 252 may be arranged at the other side of the second insulating pillar 210 in the second direction D2. For instance, the fourth source/drain area 252 may be provided in plural by being spaced apart along the third direction D3, and the pair of fourth source/drain areas 252 may be disposed on both sides of the fourth gate line 262 along the third direction D3 on the fourth active area F4. The fourth source/drain area 252 may be disposed between the plurality of fourth nano-sheet stacks NSS4 parallelly arranged along the third direction D3. The fourth source/drain area 252 may be in contact with each of the plurality of fourth nano-sheets NS4.

According to some example embodiments, the third source/drain area 251 and the fourth source/drain area 252 may be an n-type source/drain area doped with n-type impurities. For instance, the n-type impurities may include at least one of elements of phosphorus (P), arsenic (As), or antimony (Sb). Therefore, the plurality of third source/drain areas 251, the third gate line 261 and the third nano-sheet stack NSS3 may constitute an NMOS transistor. The plurality of fourth source/drain areas 252, the fourth gate line 262 and the fourth nano-sheet stack NSS4 may constitute an NMOS transistor.

According to some example embodiments, a plurality of gate cuts (e.g., a first gate cut GC1 to a third gate cut GC3) may be arranged on the substrate 100 and the plurality of field insulating films (e.g., the first field insulating film 105 to the third field insulating film 107). For instance, an upper surface of the plurality of gate cuts (e.g., the first gate cut GC1 to the third gate cut GC3) may be formed to be coplanar with an upper surface of the capping pattern 166. For instance, a bottom surface of the plurality of gate cuts (e.g., the first gate cut GC1 to the third gate cut GC3) may be formed on an inner side of the plurality of field insulating films (e.g., the first field insulating film 105 to the third field insulating film 107). In other words, a bottom surface of the plurality of gate cuts (e.g., the first gate cut GC1 to the third gate cut GC3) may be formed in the plurality of field insulating films (e.g., the first field insulating film 105 to the third field insulating film 107). However, a shape and an arrangement of the plurality of gate cuts (e.g., the first gate cut GC1 to the third gate cut GC3) are not limited thereto.

According to some example embodiments, the plurality of gate cuts (e.g., the first gate cut GC1 to the third gate cut GC3) may include the first gate cut GC1, the second gate cut GC2, and the third gate cut GC3 which are parallelly arranged along the second direction D2. The first gate cut GC1 may be disposed at one side of the first gate line 161, and the second gate cut GC2 may be disposed between the second gate line 162 and the third gate line 261. The third gate cut GC3 may be disposed at one side of the fourth gate line 262.

According to some example embodiments, the plurality of gate cuts (e.g., the first gate cut GC1 to the third gate cut GC3) may include, for instance, one of silicon nitride (SiN), silicon oxynitride (SiON), silicon oxide (SiO2), silicon oxycarbonitride (SiOCN) or a combination thereof. However, example embodiments of the present disclosure are not limited thereto.

According to some example embodiments, the first gate dielectric film 141 may be disposed between the first gate line 161 and the plurality of first nano-sheets NS1. The first gate dielectric film 141 may be disposed between the first gate line 161 and the first source/drain area 151. The first gate dielectric film 141 may be disposed between the first gate line 161 and the first active area F1. The first gate dielectric film 141 may be disposed between the first gate line 161 and the first field insulating film 105. The first gate dielectric film 141 may be disposed between the first gate line 161 and the first filling film 111.

According to some example embodiments, the second gate dielectric film 142 may be disposed between the second gate line 162 and the plurality of second nano-sheets NS2. The second gate dielectric film 142 may be disposed between the second gate line 162 and the second source/drain area 152. The second gate dielectric film 142 may be disposed between the second gate line 162 and the second active area F2. The second gate dielectric film 142 may be disposed between the second gate line 162 and the second field insulating film 106. The second gate dielectric film 142 may be disposed between the second gate line 162 and the first filling film 111.

According to some example embodiments, the third gate dielectric film 241 may be disposed between the third gate line 261 and the plurality of third nano-sheets NS3. The third gate dielectric film 241 may be disposed between the third gate line 261 and the third source/drain area 251. The third gate dielectric film 241 may be disposed between the third gate line 261 and the third active area F3. The third gate dielectric film 241 may be disposed between the third gate line 261 and the second field insulating film 106. The third gate dielectric film 241 may be disposed between the third gate line 261 and the second filling film 211.

According to some example embodiments, the fourth gate dielectric film 242 may be disposed between the fourth gate line 262 and the plurality of fourth nano-sheets NS4. The fourth gate dielectric film 242 may be disposed between the fourth gate line 262 and the fourth source/drain area 252. The fourth gate dielectric film 242 may be disposed between the fourth gate line 262 and the fourth active area F4. The fourth gate dielectric film 242 may be disposed between the fourth gate line 262 and the third field insulating film 107. The fourth gate dielectric film 242 may be disposed between the fourth gate line 262 and the second filling film 211.

According to some example embodiments, each of the first gate dielectric film 141, the second gate dielectric film 142, the third gate dielectric film 241, and the fourth gate dielectric film 242 may include at least one of silicon oxide, silicon oxynitride, silicon nitride or a high-k material with a dielectric constant being greater than silicon oxide. The high-k material may include, for instance, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

According to some example embodiments, the capping pattern 166 may be disposed on the plurality of gate lines (e.g., the first gate line 161, the second gate line 162, the third gate line 261, and the fourth gate line 262). The capping pattern 166 may be in contact with an upper surface of the plurality of gate lines (e.g., the first gate line 161, the second gate line 162, the third gate line 261, and the fourth gate line 262). For example, the capping pattern 166 may include at least one of silicon nitride (SiN), silicon oxynitride (SiON), silicon oxide (SiO2), silicon carbonitride (SiCN), silicon oxycarbonitride (SiOCN), or a combination thereof.

According to some example embodiments, a first upper filling film 124 may be disposed between the first insulating cap 123 and the first upper insulating pillar 130, and a second upper filling film 224 may be disposed between the second insulating cap 223 and the second upper insulating pillar 230. The first upper filling film 124 and the second upper filling film 224 may include an identical material to the first barrier 121, the second barrier 122, the third barrier 221, and the fourth barrier 222, the first insulating liner 112, and the second insulating liner 212.

According to some example embodiments, the first interlayer insulating film 180 may be arranged on the first field insulating film 105 to the third field insulating film 107. The first interlayer insulating film 180 may surround each of the first source/drain area 151, the second source/drain area 152, the third source/drain area 251, and the fourth source/drain area 252. The first interlayer insulating film 180 may surround the first source/drain contact CA1 and the second source/drain contact CA2 on the first source/drain area 151, the second source/drain area 152, the third source/drain area 251, and the fourth source/drain area 252. For instance, an upper surface of the first interlayer insulating film 180 may be formed to be coplanar with an upper surface of the first source/drain contact CA1 and an upper surface of the second source/drain contact CA2.

According to some example embodiments, the first interlayer insulating film 180 may include, for example, at least one of silicon oxide, silicon nitride, silicon oxynitride, or a low-k material. The low-k material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon-doped silicon oxide (CDO), organo silicate glass (OSG), SiLK, amorphous fluorinated carbon, silica aerogels, silica xerogels, mesoporous silica or a combination thereof, but example embodiments of the present disclosure are not limited thereto.

According to some example embodiments, the first source/drain contact CA1 may penetrate the first interlayer insulating film 180 in the first direction D1 to be connected with the first source/drain area 151 and the second source/drain area 152. In other words, the first source/drain contact CA1 may be a merged contact plug which is connected with the first source/drain area 151 and the second source/drain area 152. The first source/drain contact CA1 may be formed on the first source/drain area 151 and the second source/drain area 152. At least a portion of the first source/drain contact CA1 is disposed between the first source/drain area 151 and the second source/drain area 152 and may be in contact with the first insulating pillar 110.

According to some example embodiments, an upper surface of the first source/drain contact CA1 may be coplanar with an upper surface of the first interlayer insulating film 180. A drawing illustrates that the first source/drain contact CA1 is formed as a single film, but example embodiments of the present disclosure are not limited thereto. For instance, the first source/drain contact CA1 may be formed as multiple films. The first source/drain contact CA1 may include a conductive material.

According to some example embodiments, the first source/drain contact CA1 may include a first contact area CA1-1 and a second contact area CA1-2. The second contact area CA1-2 may be formed to protrude from one surface of the first contact area CA1-1 toward the first insulating pillar 110.

According to some example embodiments, the first contact area CA1-1 may be formed on an upper portion of the first source/drain area 151 and the second source/drain area 152. In other words, an upper surface of the first source/drain area 151 and an upper surface of the second source/drain area 152 may face the first contact area CA1-1. A side surface of the first contact area CA1-1 may be formed to be surrounded by the first interlayer insulating film 180. The first contact area CA1-1 may overlap the first source/drain area 151 and the second source/drain area 152 in the first direction D1 and may overlap the first gate cut GC1 and the second gate cut GC2 in the second direction D2.

According to some example embodiments, the second contact area CA1-2 may be disposed between the first source/drain area 151 and the second source/drain area 152 and between the first contact area CA1-1 and the first insulating pillar 110. The second contact area CA1-2 may be connected with the first insulating pillar 110. The second contact area CA1-2 may overlap the first insulating pillar 110 and the first contact area CA1-1 in the first direction D1 and may overlap the first source/drain area 151 and the second source/drain area 152 in the second direction D2. In other words, a side surface of the first source/drain area 151 and a side surface of the second source/drain area 152 may face each other with the second contact area CA1-2 interposed therebetween. The side surface of the first source/drain area 151 and the side surface of the second source/drain area 152 may be utilized as contact areas, which may reduce the resistance of an integrated circuit device 10.

According to some example embodiments, the second contact area CA1-2 may be formed to protrude from a portion of one surface of the first contact area CA1-1. A length of the second contact area CA1-2 in the second direction D2 may be shorter than a length of the first contact area CA1-1 in the second direction D2.

According to some example embodiments, the second source/drain contact CA2 may penetrate the first interlayer insulating film 180 in the first direction D1 to be connected with the third source/drain area 251 and the fourth source/drain area 252. In other words, the second source/drain contact CA2 may be a merged contact plug which is connected with the third source/drain area 251 and the fourth source/drain area 252. The second source/drain contact CA2 may be formed on the third source/drain area 251 and the fourth source/drain area 252. At least a portion of the second source/drain contact CA2 may be disposed between the third source/drain area 251 and the fourth source/drain area 252 and may be in contact with the second insulating pillar 210.

According to some example embodiments, an upper surface of the second source/drain contact CA2 may be coplanar with an upper surface of the first interlayer insulating film 180. A drawing illustrates that the second source/drain contact CA2 is formed as a single film, but example embodiments of the present disclosure are not limited thereto. For instance, the second source/drain contact CA2 may be formed as multiple films. The second source/drain contact CA2 may include a conductive material.

According to some example embodiments, the second source/drain contact CA2 may include a third contact area CA2-1 and a fourth contact area CA2-2. The fourth contact area CA2-2 may be formed to protrude from one surface of the third contact area CA2-1 toward the second insulating pillar 210.

According to some example embodiments, the third contact area CA2-1 may be formed on an upper portion of the third source/drain area 251 and the fourth source/drain area 252. In other words, an upper surface of the third source/drain area 251 and an upper surface of the fourth source/drain area 252 may face the third contact area CA2-1. A side surface of the third contact area CA2-1 may be formed to be surrounded by the first interlayer insulating film 180. The third contact area CA2-1 may overlap the third source/drain area 251 and the fourth source/drain area 252 in the first direction D1 and may overlap the second gate cut GC2 and the third gate cut GC3 in the second direction D2.

According to some example embodiments, the fourth contact area CA2-2 may be disposed between the third source/drain area 251 and the fourth source/drain area 252 and between the third contact area CA2-1 and the second insulating pillar 210. The fourth contact area CA2-2 may be connected with the second insulating pillar 210. The fourth contact area CA2-2 may overlap the second insulating pillar 210 and the third contact area CA2-1 in the first direction D1 and may overlap the third source/drain area 251 and the fourth source/drain area 252 in the second direction D2. In other words, a side surface of the third source/drain area 251 and a side surface of the fourth source/drain area 252 may face each other with the fourth contact area CA2-2 interposed therebetween. The side surface of the third source/drain area 251 and the side surface of the fourth source/drain area 252 may be utilized as contact areas, which may reduce the resistance of an integrated circuit device 10.

According to some example embodiments, the fourth contact area CA2-2 may be formed to protrude from a portion of one surface of the third contact area CA2-1. A length of the fourth contact area CA2-2 in the second direction D2 may be shorter than a length of the third contact area CA2-1 in the second direction D2.

According to some example embodiments, the first silicide layer 171 may be disposed between the first source/drain area 151 and the first source/drain contact CA1, and the second silicide layer 172 may be disposed between the second source/drain area 152 and the first source/drain contact CA1. The third silicide layer 271 may be disposed between the third source/drain area 251 and the second source/drain contact CA2, and the fourth silicide layer 272 may be disposed between the fourth source/drain area 252 and the second source/drain contact CA2. For example, the first silicide layer 171, the second silicide layer 172, the third silicide layer 271, and the fourth silicide layer 272 may include a metal silicide material, for instance.

According to some example embodiments, the first silicide layer 171 and the second silicide layer 172 may be spaced apart from each other along the second direction D2 with the first source/drain contact CA1 interposed therebetween. The first silicide layer 171 and the second silicide layer 172 may be symmetrical with respect to the first insulating pillar 110. In other words, a portion of the first source/drain contact CA1 may be surrounded by the first silicide layer 171 and the second silicide layer 172. In particular, in the second direction D2, a portion of the first contact area CA1-1 and the second contact area CA1-2 may be surrounded by the first silicide layer 171 and the second silicide layer 172.

According to some example embodiments, one end of the first silicide layer 171 and one end of the second silicide layer 172 may be connected with the first interlayer insulating film 180. The other end of the first silicide layer 171 and the other end of the second silicide layer 172 may be in contact with one surface of the first insulating pillar 110. In other words, one surface of the first insulating pillar 110, which is opposite to the other surface of the first insulating pillar 110 that is connected with the substrate 100, may be connected with the first silicide layer 171, the second silicide layer 172 and the second contact area CA1-2 disposed between the first silicide layer 171 and the second silicide layer 172.

According to some example embodiments, the third silicide layer 271 and the fourth silicide layer 272 may be spaced apart from each other along the second direction D2 with the second source/drain contact CA2 interposed therebetween. The third silicide layer 271 and the fourth silicide layer 272 may be symmetrical with respect to the second insulating pillar 210. In other words, a portion of the second source/drain contact CA2 may be surrounded by the third silicide layer 271 and the fourth silicide layer 272. For example, in the second direction D2, a portion of the third contact area CA2-1 and the fourth contact area CA2-2 may be surrounded by the third silicide layer 271 and the fourth silicide layer 272.

According to some example embodiments, one end of the third silicide layer 271 and one end of the fourth silicide layer 272 may be connected with the first interlayer insulating film 180. The other end of the third silicide layer 271 and the other end of the fourth silicide layer 272 may be in contact with the second insulating pillar 210. In other words, one surface of the second insulating pillar 210, which is opposite to the other surface of the second insulating pillar 210 that is connected with the substrate 100, may be connected with the third silicide layer 271, the fourth silicide layer 272 and the fourth contact area CA2-2 disposed between the third silicide layer 271 and the fourth silicide layer 272.

According to some example embodiments, the first gate contact CB1 may be connected with the first gate line 161 by penetrating the capping pattern 166 in the first direction D1. Similarly, the second gate contact CB2 to the fourth gate contact CB4 may be connected with the second gate line 162, the third gate line 261, and the fourth gate line 262, respectively, by penetrating the capping pattern 166 in the first direction D1. An upper surface of the first gate contact CB1 to the fourth gate contact CB4 may be formed to be coplanar with an upper surface of the capping pattern 166, but example embodiments of the present disclosure are limited thereto. Further, a drawing illustrates the first gate contact CB1 to the fourth gate contact CB4 being formed as a single film, but example embodiments of the present disclosure are not limited thereto. For instance, the first gate contact CB1 to the fourth gate contact CB4 may be formed as multiple films. For instance, the first gate contact CB1 to the fourth gate contact CB4 may include a conductive material.

According to some example embodiments, the etching stopping film 191 may be disposed on an upper surface of each of the capping pattern 166, the first gate cut GC1 to the third gate cut GC3, the first gate contact CB1 to the fourth gate contact CB4, the first source/drain contact CA1 and the second source/drain contact CA2. For instance, the etching stopping film 191 may be conformally formed. A drawing illustrates the etching stopping film 191 being formed as a single film, but example embodiments of the present disclosure are not limited thereto. For instance, the etching stopping film 191 may be formed as multiple films. For instance, the etching stopping film 191 may include at least one of aluminum oxide, aluminum nitride, hafnium oxide, zirconium oxide, silicon oxide, silicon nitride, silicon oxynitride, or a low-k material.

According to some example embodiments, the second interlayer insulating film 192 may be arranged on the etching stopping film 191. The second interlayer insulating film 192 may include, for instance, at least one of silicon oxide, silicon nitride, silicon oxynitride, or a low-k material.

According to some example embodiments, the first via V1 to the fourth via V4 may be formed by penetrating the second interlayer insulating film 192 and the etching stopping film 191 in the first direction D1. The first via V1 may be connected with the first gate contact CB1, the second via V2 may be connected with the second gate contact CB2, the third via V3 may be connected with the third gate contact CB3, and the fourth via V4 may be connected with the fourth gate contact CB4. A drawing illustrates the first via V1 to the fourth via V4 being formed as a single film, but example embodiments of the present disclosure are not limited thereto. For instance, the first via V1 to the fourth via V4 may be formed as multiple films. For instance, the first via V1 to the fourth via V4 may include a conductive material.

According to some example embodiments, a first source/drain via SV1 to a fourth source/drain via SV4 may be formed by penetrating the second interlayer insulating film 192 and the etching stopping film 191 in the first direction D1. The first source/drain via SV1 and the second source/drain via SV2 may be connected with the first source/drain contact CA1. The first source/drain via SV1 and the second source/drain via SV2 may be electrically connected through the first source/drain contact CA1. The third source/drain via SV3 and the fourth source/drain via SV4 may be connected with the second source/drain contact CA2. A drawing illustrates the first source/drain via SV1 to the fourth source/drain via SV4 being formed as a single film, but example embodiments of the present disclosure are not limited thereto. For instance, the first source/drain via SV1 to the fourth source/drain via SV4 may be formed as multiple films. For instance, the first source/drain via SV1 to the fourth source/drain via SV4 may include a conductive material.

According to some example embodiments, a first source/drain via structure (e.g., the first source/drain via SV1 and the second source/drain via SV2) may be connected with the first source/drain contact CA1, and a second source/drain via structure (e.g., the third source/drain via SV3 and the fourth source/drain via SV4) may be connected with the second source/drain contact CA2. A drawing illustrates an image of the first source/drain via structure including the first source/drain via SV1 and the second source/drain via SV2, and the second source/drain via structure including the third source/drain via SV3 and the fourth source/drain via SV4, but a number of the vias is not limited thereto. For instance, the first source/drain via structure and the second source/drain via structure may include one via or three or more vias.

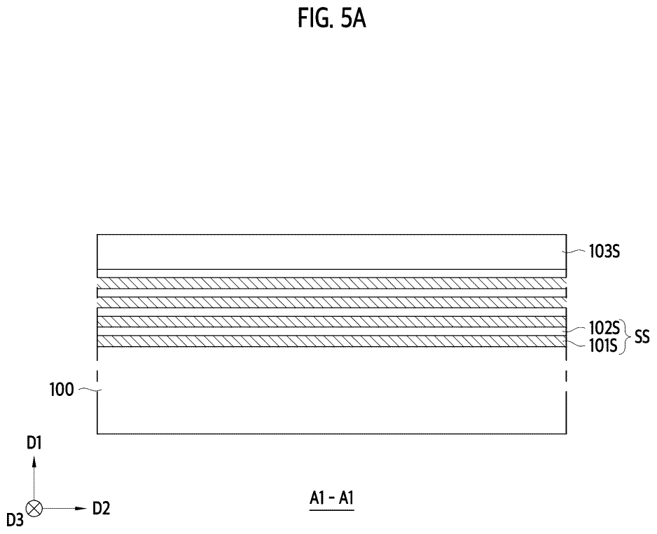

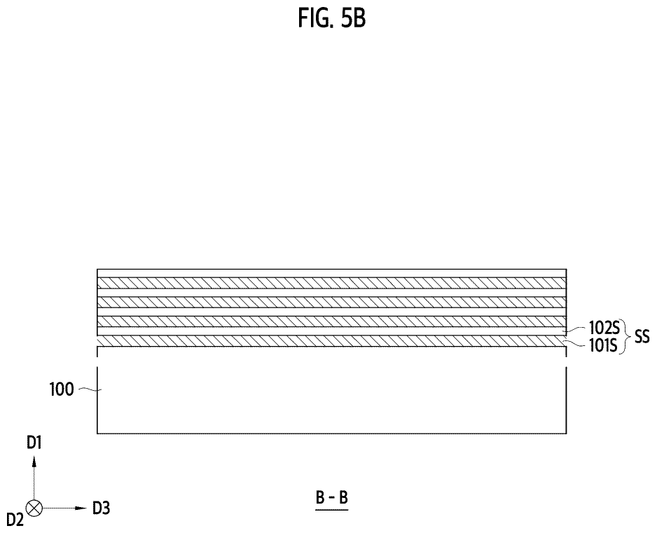

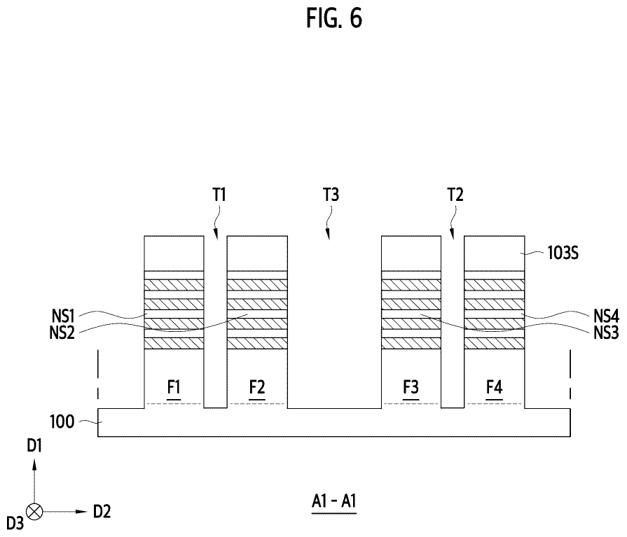

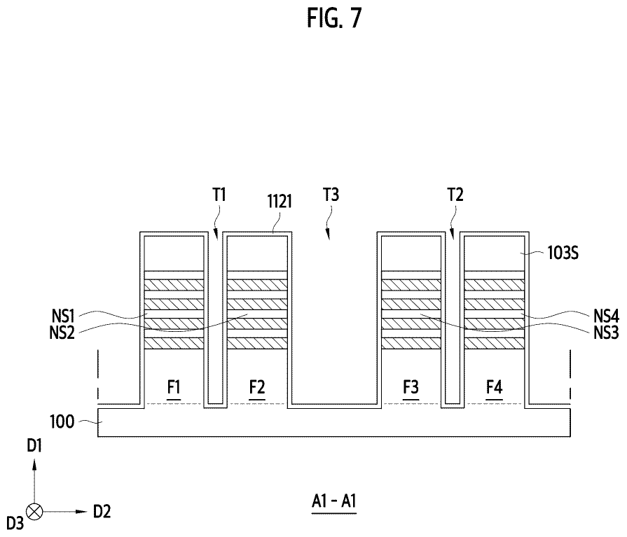

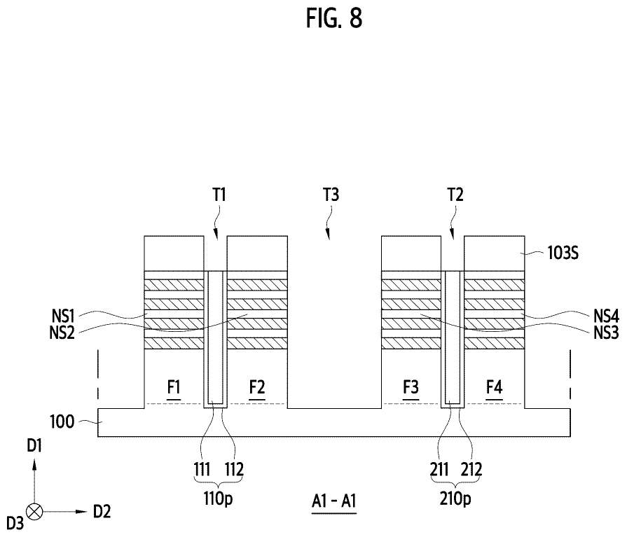

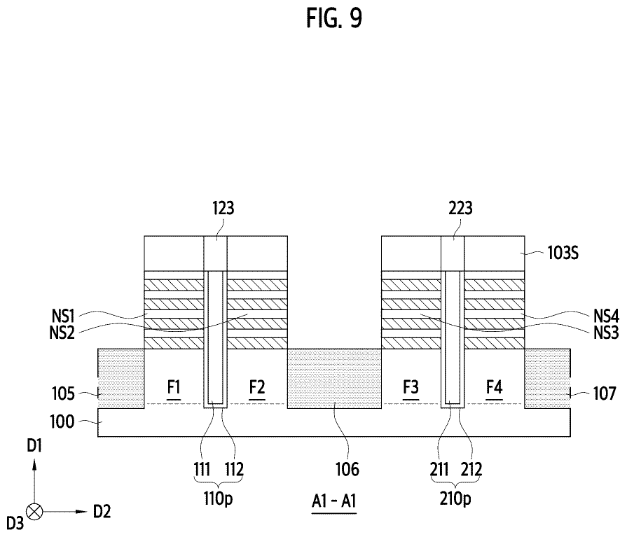

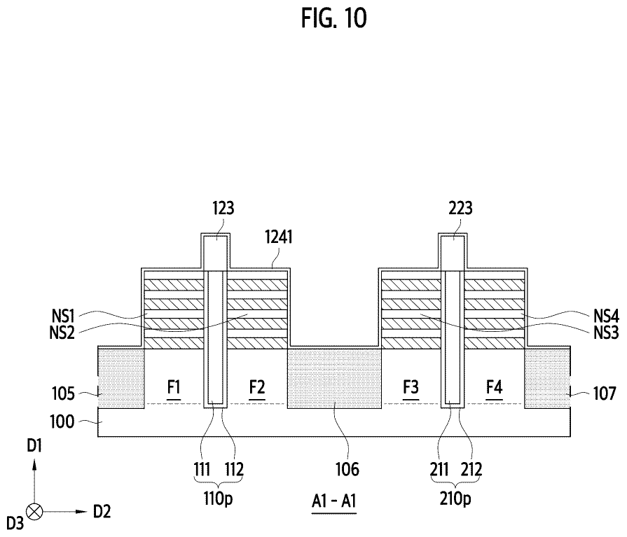

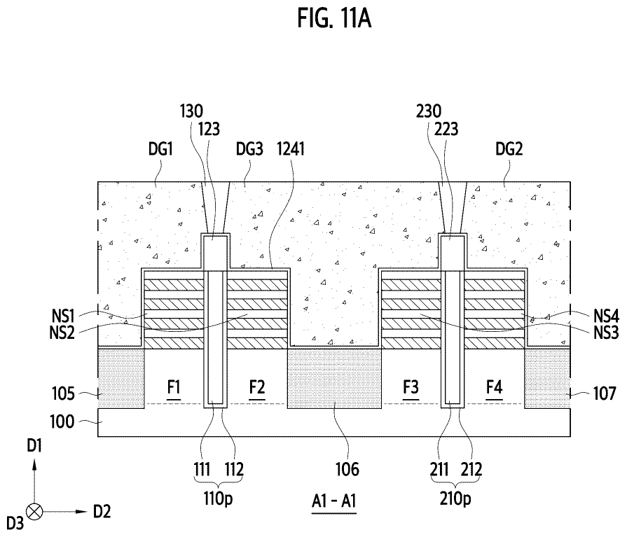

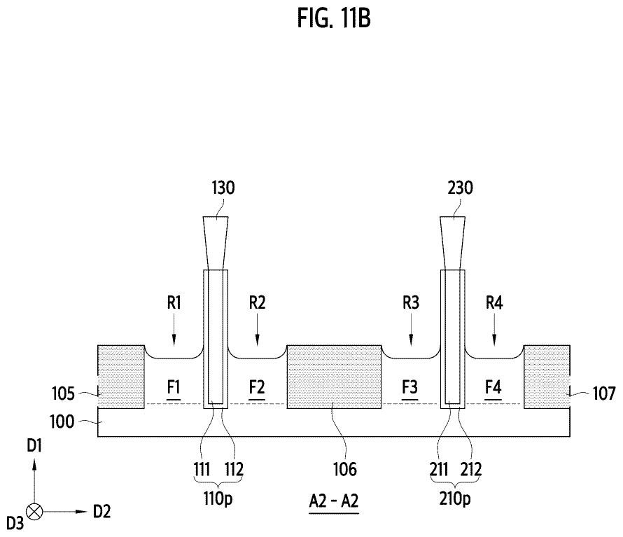

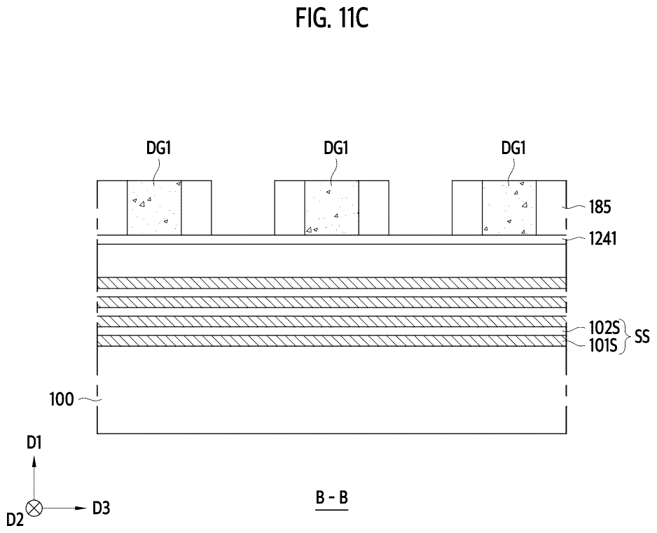

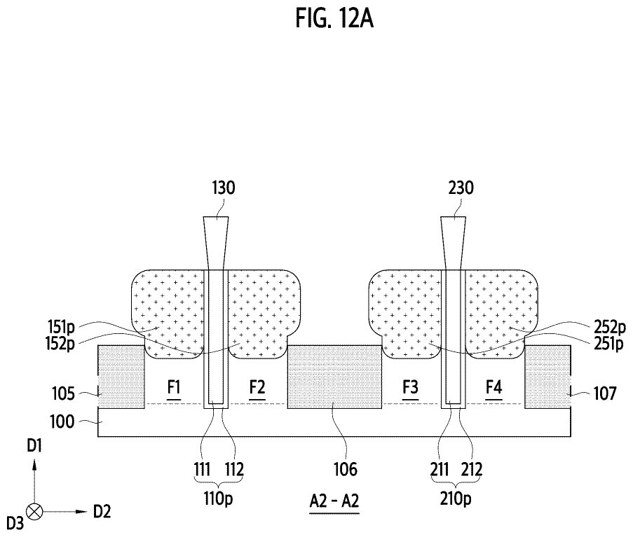

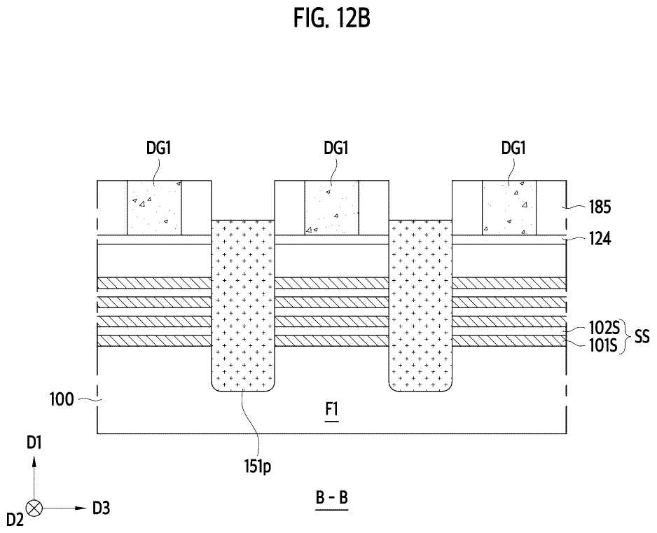

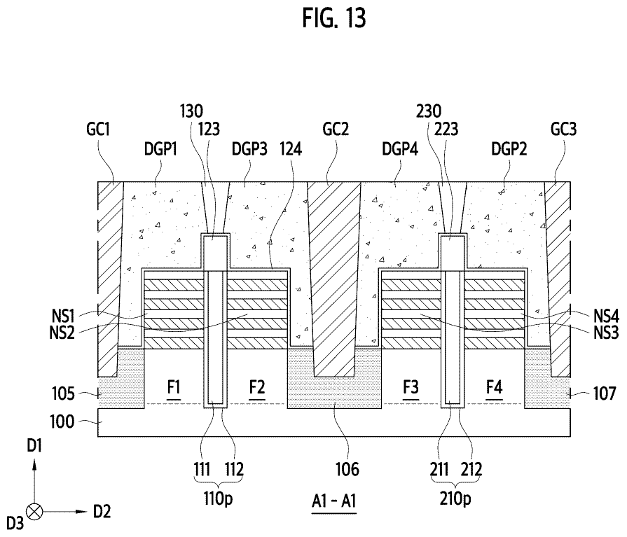

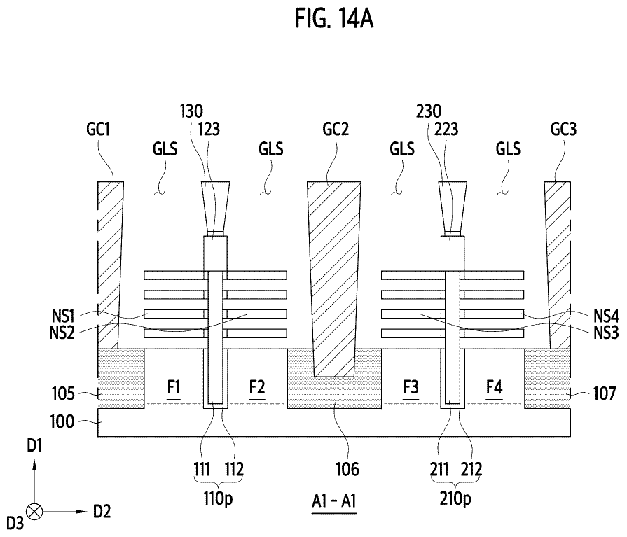

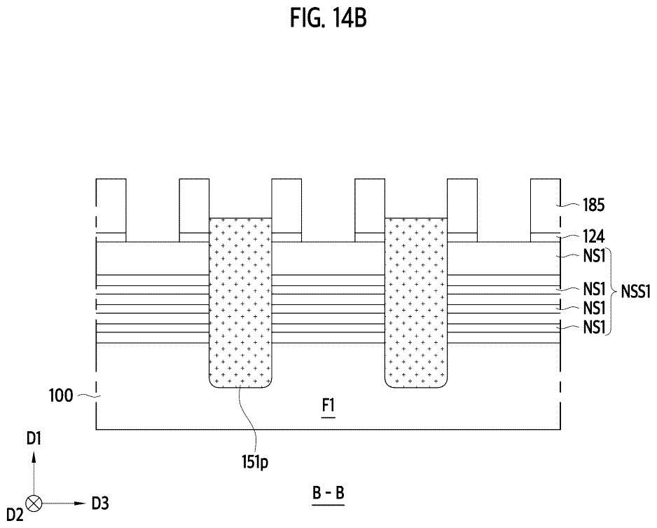

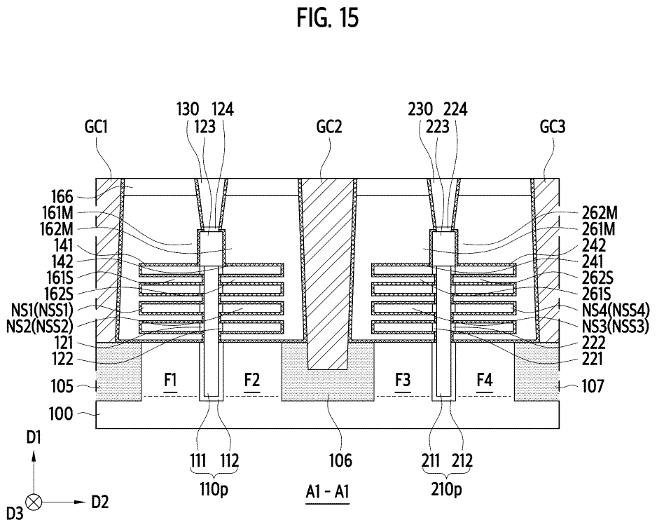

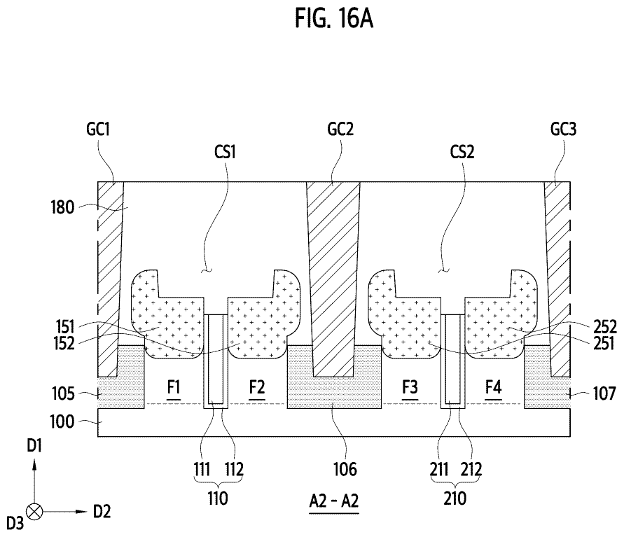

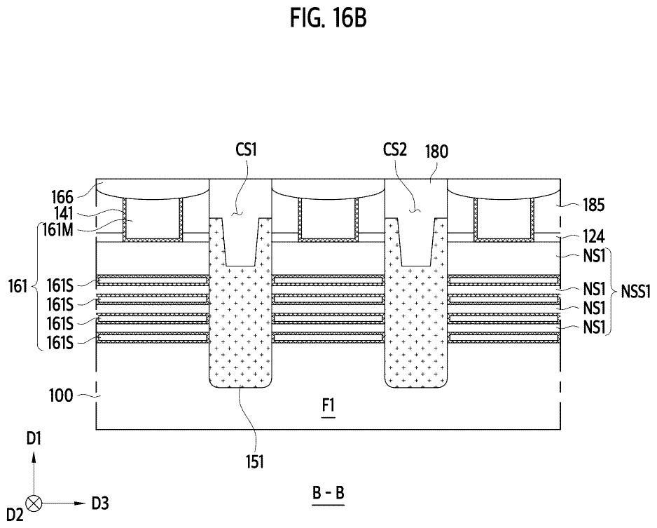

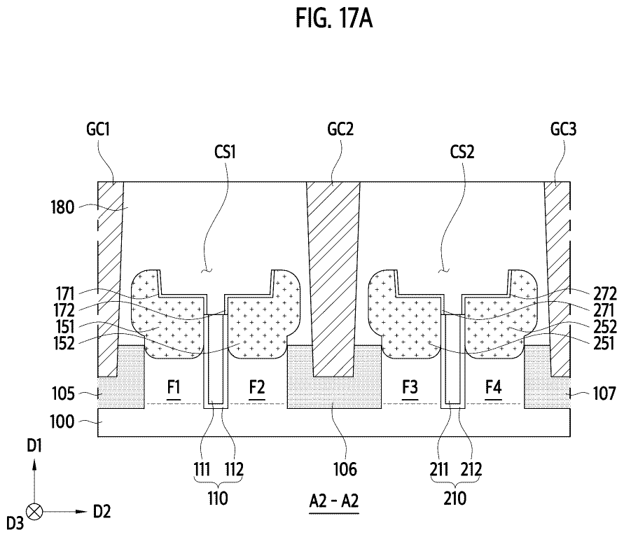

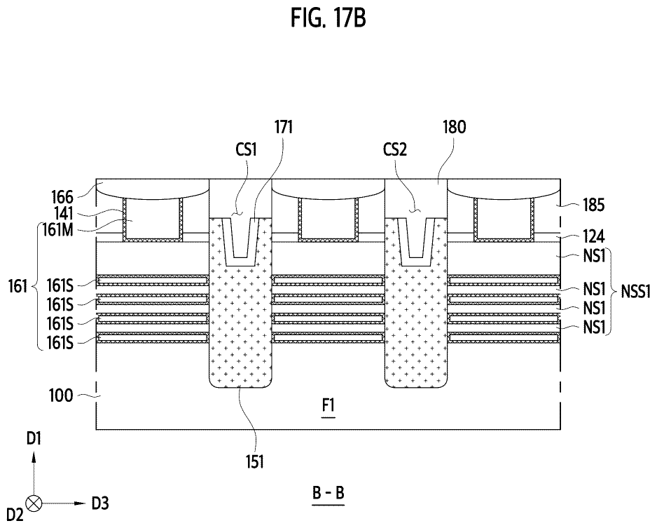

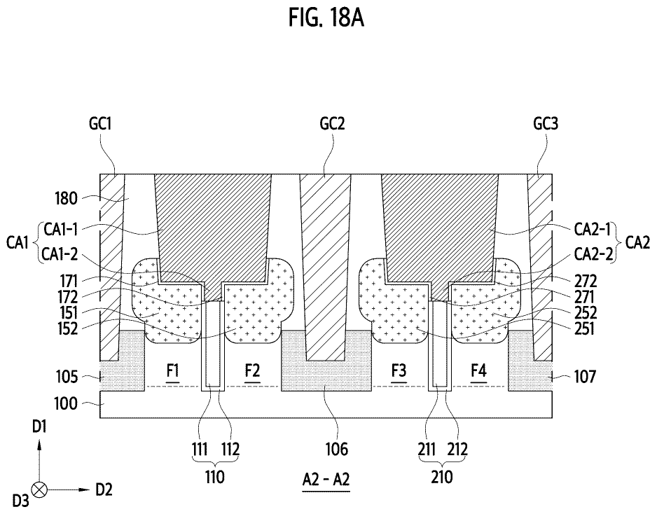

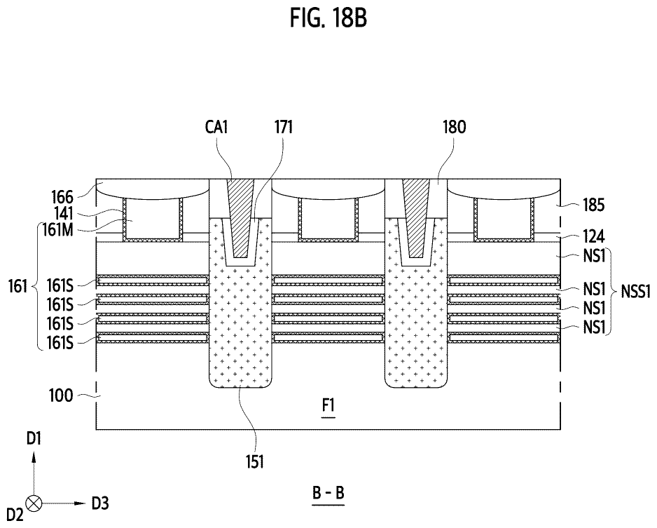

FIG. 5 to FIG. 18B are diagrams illustrating a manufacturing method of the integrated circuit device 10 according to an example embodiment, wherein FIG. 5A, FIG. 6, FIG. 7, FIG. 8, FIG. 9, FIG. 10, FIG. 11A, FIG. 13, FIG. 14A, and FIG. 15 are diagrams illustrating a process of manufacturing a portion corresponding to a cross section taken along A1-A1, and wherein FIG. 11B, FIG. 12A, FIG. 16A, FIG. 17A, and FIG. 18A are diagrams illustrating a process of manufacturing a portion corresponding to a cross section taken along A2-A2, and wherein FIG. 5B, FIG. 11C, FIG. 12B, FIG. 14B, FIG. 16B, FIG. 17B, and FIG. 18B are diagrams illustrating a process of manufacturing a portion corresponding to a cross section taken along B-B.

Referring to FIG. 5A and FIG. 5B, formed is a stacked structure SS in which a sacrificial film 101S and a semiconductor layer 102S are alternatingly stacked on the substrate 100. For instance, the sacrificial film 101S is formed at a lowermost portion of the stacked structure SS, and the semiconductor layer 102S may be formed at an uppermost portion of the stacked structure SS. However, example embodiments of the present disclosure are not limited thereto. In some example embodiments, the sacrificial film 101S may be formed at the uppermost portion of the stacked structure SS. The sacrificial film 101S and the semiconductor layer 102S may be made of or include semiconductor materials different from each other. The plurality of semiconductor layers 102S may be made of a single material. In some example embodiments, the plurality of semiconductor layers 102S may be made of or include an identical material to a material constituting or included in the substrate 100. For instance, the sacrificial film 101S may include silicon germanium (SiGe), and the semiconductor layer 102S may include silicon (Si), but example embodiments of the present disclosure are not limited thereto.

According to some example embodiments, a capping layer 103S may be formed above or on the stacking structure SS. The capping layer 103S may extend along an upper surface of the semiconductor layer 102S. For instance, the capping layer 103S may include one of silicon nitride (SiN), silicon oxynitride (SiON), silicon oxide (SiO2), silicon oxycarbonitride (SiOCN) or a combination thereof. However, example embodiments of the present disclosure are not limited thereto.

Referring to FIG. 6, a plurality of trenches (e.g., a first trench T1, a second trench T2, and a third trench T3) may be formed by etching a portion of the capping layer 103S, the stacked structure SS, and the substrate 100. Each of the first active area F1 to the fourth active area F4 may be formed to extend in the third direction D3 on the substrate 100. The first active area F1 to the fourth active area F4 may be disposed to be spaced apart from each other in the third direction D2. The plurality of nano-sheets (the first nano-sheet NS1, the second nano-sheet NS2, the third nano-sheet NS3, and the fourth nano-sheet NS4) which are spaced apart along the second direction D2 and extend in the third direction D3 may be formed by etching the plurality of semiconductor layers 102S (refer to FIG. 5A). The first trench T1 may be formed between the first nano-sheet NS1 and the second nano-sheet NS2, the second trench T2 may be formed between the third nano-sheet NS3 and the fourth nano-sheet NS4, and the third trench T3 may be formed between the second nano-sheet NS2 and the third nano-sheet NS3.

Referring to FIG. 7, an insulating material layer 1121 covering the active areas (e.g., the first active area F1 to the fourth active area F4), the plurality of nano-sheets (e.g., the first nano-sheet NS1 to the fourth nano-sheet NS4), the plurality of sacrificial films 101S, a side wall of the capping layer 103S, and an upper surface of the capping layer 103S may be formed on the substrate 100. The insulating material layer 1121 may be conformally formed. For instance, the insulating material layer 1121 may include silicon oxide (SiO2) or silicon nitride (SiN). For instance, the insulating material layer 1121 may be formed by means of processes such as a chemical vapor deposition (CVD) method, a physical vapor deposition method (PVD), or an atomic layer deposition (ALD) method, but a process of depositing the insulating material layer 1121 is not limited to the aforementioned processes.

Referring to FIG. 8, the first filling film 111 may be formed in the first trench T1, and the second filling film 221 may be formed in the second trench T2. After the first filling film 111 and the second filling film 211 are formed, the first insulating liner 112 and the second insulating liner 212 may be formed by etching a portion of the insulating material layer 1121. In the process, a pre-first insulating pillar 110p and a pre-second insulating pillar 210p may be formed.

Referring to FIG. 9, the first insulating cap 123 may be formed on the pre-first insulating pillar 110p in the first trench T1, and the second insulating cap 223 may be formed on the pre-second insulating pillar 210p in the second trench T2.

According to some example embodiments, the plurality of field insulating films (e.g., the first field insulating film 105 to the third field insulating film 107) may be formed on the substrate 100. For instance, the first field insulating film 105 may be formed to cover a side wall of the first active area F1, the second field insulating film 106 may be formed to cover a side wall of the second active area F2 and a side wall of the third active area F3, and the third field insulating film 107 may be formed to cover a side wall of the fourth active area F4.

Referring to FIG. 10, the capping layer 103S is removed, and an upper insulating material 1241 may be formed to cover the plurality of nano-sheets (e.g., the first nano-sheet NS1 to the fourth nano-sheet NS4), a side wall of the first insulating cap 123, a side wall of the second insulating cap 223, an upper surface of the first insulating cap 123, and an upper surface of the second insulating cap 223, on the plurality of field insulating films (e.g., the first field insulating film 105 to the third field insulating film 107). For instance, the upper insulating material 1241 may be conformally formed. A material included by the upper insulating material 1241 and a process of depositing the upper insulating material 1241 may be identical to the insulating material layer 1121 (refer to FIG. 7).

Referring to FIG. 11A, FIG. 11B, and FIG. 11C, the first upper insulating pillar 130 may be formed to overlap the pre-first insulating pillar 110p in the first direction D1, and the second upper insulating pillar 230 may be formed to overlap the pre-second insulating pillar 210p in the first direction D1. The first upper insulating pillar 130 and the second upper insulating pillar 230 may be formed by means of a lithography process and the like, but a process of forming the first upper insulating pillar 130 and the second upper insulating pillar 230 is not limited thereto.

According to some example embodiments, a first dummy gate DG1, a second dummy gate DG2, and a third dummy gate DG3 may be formed on the upper insulating material 1241. The first dummy gate DG1, the second dummy gate DG2, and the third dummy gate DG3 may be disposed to be spaced apart from each other in the second direction D2. A gate spacer 185 may be formed to extend along both side walls of each of the first dummy gate DG1 to the third dummy gate DG3 in the second direction D2.

According to some example embodiments, a portion of the plurality of nano-sheets (e.g., the first nano-sheet NS1 to the fourth nano-sheet NS4), a portion of the plurality of insulating caps (e.g., the first insulating cap 123 and the second insulating cap 223), a portion of the plurality of sacrificial films 101S, and a portion of the upper insulating material 1241 may be removed by the etching process. Further, a portion of the first active area F1 to the fourth active area F4 may be removed by means of the etching process, in order to form a first recess R1 to a fourth recess R4. Each of the first recess R1 to the fourth recess R4 may be defined as an etched area at a portion of a corresponding one of the first active area F1 to the fourth active area F4. Hereinafter, the term “pre” may signify an intermediate structure before being formed into a final structure.

Referring to FIG. 12A and FIG. 12B, the pre-first source/drain area 151p may be formed between the pair of adjacent first nano-sheets NS1 arranged in the third direction D3 at the first recess R1. Further, the pre-second source/drain area 152p may be formed between the pair of adjacent second nano-sheets NS2 arranged in the third direction D3 at the second recess R2. Further, the pre-third source/drain area 251p may be formed between the pair of adjacent third nano-sheets NS3 arranged in the third direction D3 at the third recess R3. Further, the pre-fourth source/drain area 252p may be formed between the pair of adjacent fourth nano-sheets NS4 arranged in the third direction D3 at the fourth recess R4. The pre-first source/drain area 151p, the pre-second source/drain area 152p, the pre-third source/drain area 251p and the pre-fourth source/drain area 252p may be formed by epitaxially growing a semiconductor material on the first recess R1 to the fourth recess R4, respectively.

According to some example embodiments, a portion of the upper insulating material 1241, a portion of the plurality of sacrificial films 101S, a portion of the plurality of nano-sheets (the first nano-sheet NS1 to the fourth nano-sheet NS4) and a portion of the first active area F1 to the fourth active area F4 may be etched. A first upper filling film 124 may be a portion remaining after the upper insulating material 1241 is etched.

Referring to FIG. 13, the first gate cut GC1 to the third gate cut GC3 may be formed by penetrating the first dummy gate DG1 to the third dummy gate DG3 (refer to FIG. 11A), respectively, in the first direction D1. The first gate cut GC1 to the third gate cut GC3 may be formed to separate the first dummy gate DG1 to the third dummy gate DG3 from each other. Each of the first gate cut GC1 to the third gate cut GC3 may be formed by penetrating a portion of a corresponding one of the first field insulating film 105 to the third field insulating film 107. The first dummy gate DG1 to the third dummy gate DG3 may be separated by the first gate cut GC1 to the third gate cut GC3 and the first upper insulating pillar 130 and the second upper insulating pillar 230 and form a first dummy gate pattern DGP1 to a fourth dummy gate pattern DGP4.

Referring to FIG. 14A and FIG. 14B, the first dummy gate pattern DGP1 to the fourth dummy gate pattern DGP4 and the first upper filling film 124 may be removed to form a gate space GLS. As the gate space GLS is formed, at least a portion of the first nano-sheet stack NSS1 to the fourth nano-sheet stack NSS4 may be exposed.

Referring to FIG. 15, the plurality of gate dielectric films (e.g., the first gate dielectric film 141, the second gate dielectric film 142, the third gate dielectric film 241, and the fourth gate dielectric film 242) may be formed at a portion of the gate space GLS to cover exposed surfaces of the first nano-sheet NS1 to the fourth nano-sheet NS4, exposed surfaces of the first gate cut GC1 to the third gate cut GC3, and an exposed surface of the first active area F1 to the fourth active area F4.

According to some example embodiments, the first gate line 161, the second gate line 162, the third gate line 261 and the fourth gate line 262 may be formed to fill a portion of the gate space GLS on corresponding ones of the first gate dielectric film 141, the second gate dielectric film 142, the third gate dielectric film 241, and the fourth gate dielectric film 242, respectively.

According to some example embodiments, the first gate line 161 may include the first main gate part 161M which covers an upper surface of the first nano-sheet stack NSS1 and the plurality of first sub-gate parts 161S which are connected with the first main gate part 161M and are formed at a space between the plurality of first nano-sheets NS1 and between the first active area F1 and the plurality of first nano-sheets NS1.

According to some example embodiments, the second gate line 162 may include the second main gate part 162M which covers an upper surface of the second nano-sheet stack NSS2 and the plurality of second sub-gate parts 162S which are connected with the second main gate part 162M and are formed at a space between the plurality of second nano-sheets NS2 and between the second active area F2 and the plurality of second nano-sheets NS2.

According to some example embodiments, the third gate line 261 may include the third main gate part 261M which covers an upper surface of the first nano-sheet stack NSS3 and the plurality of third sub-gate parts 261S which are connected with the third main gate part 261M and are formed at a space between the plurality of third nano-sheets NS 3 and between the third active area F3 and the plurality of third nano-sheets NS3.

According to some example embodiments, the fourth gate line 262 may include the fourth main gate part 262M which covers an upper surface of the fourth nano-sheet stack NSS4 and the plurality of fourth sub-gate parts 262S which are connected with the fourth main gate part 262M and are formed at a space between the plurality of fourth nano-sheets NS4 and between the fourth active area F4 and the plurality of fourth nano-sheets NS4.

According to some example embodiments, the capping pattern 166 may be formed on the first gate line 161, the second gate line 162, the third gate line 261, and the fourth gate line 262.

Referring to FIG. 16A and FIG. 16B, a portion of the pre-first source/drain area 151p, the pre-second source/drain area 152p, the pre-third source/drain area 251p, and the pre-fourth source/drain area 252p (refer to FIG. 12A), a portion of the pre-first insulating pillar 110p (refer to FIG. 12A), and a portion of the pre-second insulating pillar 210p (refer to FIG. 12A) may be etched.

According to some example embodiments, a portion remaining after the pre-first source/drain area 151p, the pre-second source/drain area 152p, the pre-third source/drain area 251p, and the pre-fourth source/drain area 252p are etched may be the first source/drain area 151, the second source/drain area 152, the third source/drain area 251, and the fourth source/drain area 252, respectively. A portion remaining after the pre-first insulating pillar 110p is etched may be the first insulating pillar 110, and a portion remaining after the pre-second insulating pillar 210p is etched may be the second insulating pillar 210.

According to some example embodiments, the first source/drain contact space CS1 may be formed at an area at which the pre-first source/drain area 151p, the pre-second source/drain area 152p, and the pre-first insulating pillar 110p are etched. The second source/drain contact space CS2 may be formed at an area at which the pre-third source/drain area 251p, the pre-fourth source/drain area 252p, and the pre-second insulating pillar 210p are etched.

According to some example embodiments, the pre-first insulating pillar 110p may include a material with an etch selectivity different from the pre-first source/drain area 151p and the pre-second source/drain area 152p. Therefore, a portion corresponding to the first insulating pillar 110 at the first source/drain contact space CS1 may be deeply formed in the first direction D1 compared to a portion corresponding to each of the first source/drain area 151 and the second source/drain area 152.

According to some example embodiments, the pre-second insulating pillar 210p may include a material with an etch selectivity different from the pre-third source/drain area 251p and the pre-fourth source/drain area 252p. Therefore, a portion corresponding to the second insulating pillar 210 at the second source/drain contact space CS2 may be deeply formed in the first direction D1 compared to a portion corresponding to each of the third source/drain area 251 and the fourth source/drain area 252.

Referring to FIG. 17A and FIG. 17B, the first silicide layer 171 and the second silicide layer 172 may be formed along an edge of the first source/drain contact space CS1 at portions corresponding to the first source/drain area 151 and the second source/drain area 152, respectively. The third silicide layer 271 and the fourth silicide layer 272 may be formed along an edge of the second source/drain contact space CS2 at portions corresponding to the third source/drain area 251 and the fourth source/drain area 252, respectively.

Referring to FIG. 18A and FIG. 18B, the first interlayer insulating film 180 may be formed to cover the first source/drain area 151, the second source/drain area 152, the third source/drain area 251, and the fourth source/drain area 252 on the first field insulating film 105 to the third field insulating film 107. The first interlayer insulating film 180 may include silicon oxide.

According to some example embodiments, the first source/drain contact CA1 may be formed at the first source/drain contact space CS1. The second contact area CA1-2 may be formed at a space at which the pre-first insulating pillar 110p is etched, and a remaining portion excluding the second contact area CA1-2 may be the first contact area CA1-1. The first silicide layer 171, the second silicide layer 172, and the second contact area CA1-2 may be formed at a space at which the pre-first insulating pillar 110p is etched. Therefore, a length of the first insulating pillar 110 in the second direction D2 may be identical to a value that is a sum of a length of the second contact area CA1-2 in the second direction D2, a thickness of the first silicide layer 171 in the second direction D2, and a thickness of the second silicide layer 172 in the second direction D2.

According to some example embodiments, the second source/drain contact CA2 may be formed at the second source/drain contact space CS2. The fourth contact area CA2-2 may be formed at a space at which the pre-second insulating pillar 210p is etched, and a remaining portion excluding the fourth contact area CA2-2 may be the third contact area CA2-1. The third silicide layer 271, the fourth silicide layer 272, and the fourth contact area CA2-2 may be formed at a space at which the pre-second insulating pillar 210p is etched. Therefore, a length of the second insulating pillar 210 in the second direction D2 may be identical to a value that is a sum of a length of the fourth contact area CA2-2 in the second direction D2, a thickness of the third silicide layer 271 in the second direction D2, and a thickness of the fourth silicide layer 272 in the second direction D2.

According to some example embodiments, succeeding a result manufactured by a process of FIG. 18A and FIG. 18B, the first gate contact CB1 to the fourth gate contact CB4, the etching stopping film 191, the second interlayer insulating film 192, the first via V1 to the fourth via V4, and the first source/drain via SV1 to the fourth source/drain via SV4 may be formed. Accordingly, the integrated circuit device 10 illustrated in FIG. 1 to FIG. 4 may be manufactured.

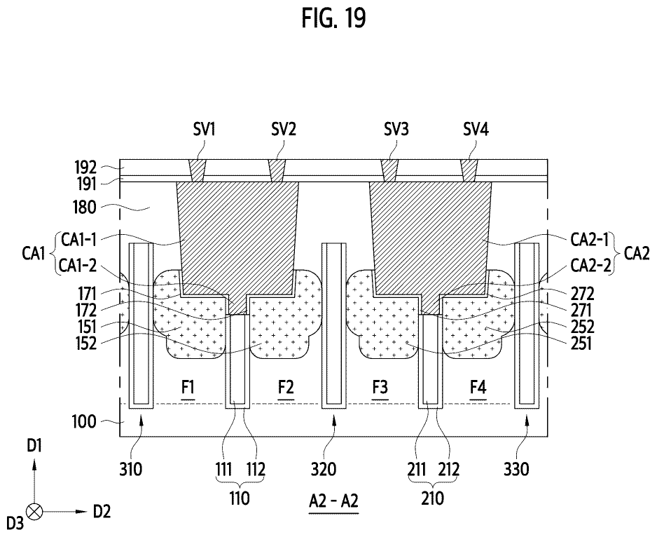

FIG. 19 is a diagram illustrating an image of cutting the integrated circuit device 10 according to another example embodiment. More specifically, FIG. 19 is a diagram illustrating an image of cutting a portion of the integrated circuit device 10 corresponding to A2-A2 of FIG. 1 according to another example embodiment. For instance, FIG. 19 may correspond to FIG. 3.

Referring to FIG. 19, the integrated circuit device 10 may include a first separating pillar 310, a second separating pillar 320, and a third separating pillar 330. The first separating pillar 310, the second separating pillar 320, and the third separating pillar 330 may be spaced apart from each other in the second direction.

According to some example embodiments, the first source/drain area 151 may be disposed between the first insulating pillar 110 and the first separating pillar 310, and the second source/drain area 152 may be disposed between the first insulating pillar 110 and the second separating pillar 320. The third source/drain area 251 may be disposed between the second insulating pillar 210 and the second separating pillar 320, and the fourth source/drain area 252 may be disposed between the second insulating pillar 210 and the third separating pillar 330.

According to some example embodiments, an upper end of the first separating pillar 310, an upper end of the second separating pillar 320, and an upper end of the third separating pillar 330 may be disposed in the first interlayer insulating film 180 on a plane including the first direction D1 and the second direction D2. In other words, an upper end of the first separating pillar 310, an upper end of the second separating pillar 320, and an upper end of the third separating pillar 330 may be disposed between the substrate 100 and the etching stopping film 191 in the first direction D1.

According to some example embodiments, the first separating pillar 310 may be in contact with the first source/drain area 151. The second separating pillar 320 may be in contact with the second source/drain area 152 and the third source/drain area 251. The third separating pillar 330 may be in contact with the fourth source/drain area 252.

While various example embodiments of the present disclosure are described in detail above, the scope of the present disclosure is not limited thereto, and it will be apparent to those of ordinary skill in the art that various modifications and variations may be made without departing from the technical idea of the present disclosure as defined by the appended claims. In addition, the aforementioned example embodiments may be implemented with some elements removed, and each example embodiment may be implemented in combination with each other.

What is claimed is:

1. An integrated circuit device comprising:
a substrate;
an insulating pillar extending in a first direction, the first direction intersecting one surface of the substrate;
a first source/drain area at one side of the insulating pillar in a second direction, the second direction intersecting the first direction;
a second source/drain area at another side of the insulating pillar and spaced apart from the first source/drain area in the second direction;
a first source/drain contact including at least a portion being in the first source/drain area and the second source/drain area;
a first silicide layer between the first source/drain area and the first source/drain contact; and
a second silicide layer between the second source/drain area and the first source/drain contact,
wherein the first source/drain contact is connected with the insulating pillar.

2. The integrated circuit device of claim 1, wherein the first source/drain contact comprises:
a first contact area; and
a second contact area protruding from one surface of the first contact area toward the insulating pillar and surrounded by the first silicide layer and the second silicide layer.

3. The integrated circuit device of claim 2, wherein
the first contact area overlaps the first source/drain area and the second source/drain area in the first direction,
the second contact area overlaps the insulating pillar and the first contact area in the first direction, and
the second contact area overlaps the first source/drain area and the second source/drain area in the second direction.

4. The integrated circuit device of claim 2, wherein a length of the second contact area in the second direction is shorter than a length of the first contact area in the second direction.

5. The integrated circuit device of claim 2, wherein a length of the insulating pillar in the second direction is identical to a value that is a sum of a length of the second contact area in the second direction, a thickness of the first silicide layer in the second direction, and a thickness of the second silicide layer in the second direction.

6. The integrated circuit device of claim 2, wherein
one surface of the insulating pillar is connected with the substrate, and
another surface of the insulating pillar is connected with the second contact area, the first silicide layer and the second silicide layer.

7. The integrated circuit device of claim 1, wherein
the first silicide layer is in contact with the insulating pillar, and
the second silicide layer is in contact with the insulating pillar.

8. The integrated circuit device of claim 1, further comprising:
a first source/drain via connected with the first source/drain contact; and
a second source/drain via connected with the first source/drain contact, the second source/drain via spaced apart from the first source/drain via in the second direction.

9. The integrated circuit device of claim 8, wherein the first source/drain via and the second source/drain via are electrically connected through the first source/drain contact.

10. The integrated circuit device of claim 1, further comprising:
a first gate cut spaced apart from the insulating pillar in the second direction with the first source/drain area interposed therebetween; and
a second gate cut spaced apart from the insulating pillar in the second direction with the second source/drain area interposed therebetween.

11. The integrated circuit device of claim 1, further comprising:
a first separating pillar spaced apart from the insulating pillar with the first source/drain area interposed therebetween; and
a second separating pillar spaced apart from the insulating pillar with the second source/drain area interposed therebetween.

12. The integrated circuit device of claim 11, wherein
the first separating pillar is in contact with the first source/drain area, and
the second separating pillar is in contact with the second source/drain area.

13. The integrated circuit device of claim 1, wherein the first silicide layer and the second silicide layer are symmetrical with respect to the insulating pillar.

14. The integrated circuit device of claim 1, wherein the insulating pillar comprises:
a filling film extending in the first direction; and
an insulating liner configured to cover a side wall of the filling film and a bottom surface of the filling film.

15. An integrated circuit device comprising:
a substrate;
a first insulating pillar extending in a first direction, the first direction intersecting one surface of the substrate;
a second insulating pillar spaced apart from the first insulating pillar in a second direction, the second direction intersecting the first direction;
a first source/drain area at one side of the first insulating pillar in the second direction;
a second source/drain area spaced apart from the first source/drain area in the second direction with the first insulating pillar interposed therebetween;
a third source/drain area at one side of the second insulating pillar in the second direction;
a fourth source/drain area spaced apart from the third source/drain area in the second direction with the second insulating pillar interposed therebetween;
a first source/drain contact comprising a first contact area and a second contact area, the second contact area protruding from one surface of the first contact area toward the first insulating pillar; and
a second source/drain contact comprising a third contact area and a fourth contact area, the fourth contact area protruding from one surface of the third contact area toward the second insulating pillar.

16. The integrated circuit device of claim 15, wherein
a length of the second contact area in the second direction is shorter than a length of the first contact area in the second direction, and
a length of the fourth contact area in the second direction is shorter than a length of the third contact area in the second direction.

17. The integrated circuit device of claim 16, further comprising:
a first source/drain via structure electrically connected with the first source/drain contact; and
a second source/drain via structure electrically connected with the second source/drain contact and spaced apart from the first source/drain via structure in the second direction.

18. The integrated circuit device of claim 17, wherein
the first source/drain area and the second source/drain area comprise p-type impurities, and
the third source/drain area and the fourth source/drain area comprise n-type impurities.

19. The integrated circuit device of claim 15, further comprising:
a first silicide layer between the first source/drain area and the first source/drain contact;
a second silicide layer between the second source/drain area and the first source/drain contact;
a third silicide layer between the third source/drain area and the second source/drain contact; and
a fourth silicide layer between the fourth source/drain area and the second source/drain contact,
wherein the first silicide layer and the second silicide layer overlap the first contact area in the first direction and overlap the second contact area in the second direction, and
wherein the third silicide layer and the fourth silicide layer overlap the third contact area in the first direction and overlap the fourth contact area in the second direction.

20. An integrated circuit device comprising:
a substrate;
an insulating pillar extending in a first direction, the first direction intersecting one surface of the substrate;
a first source/drain area at one side of the insulating pillar in a second direction, the second direction intersecting the first direction;
a second source/drain area at another side of the insulating pillar and spaced apart from the first source/drain area in the second direction;
a first source/drain contact comprising a first contact area and a second contact area, the first contact area including a portion being in the first source/drain area and the second source/drain area, the second contact area protruding from one surface of the first contact area toward the insulating pillar;
a first silicide layer between the first source/drain area and the first source/drain contact; and
a second silicide layer between the second source/drain area and the first source/drain contact,
wherein the first source/drain contact is connected with the insulating pillar,
wherein an upper surface of the first source/drain area and an upper surface of the second source/drain area face the first contact area, and
wherein a side surface of the first source/drain area and a side surface of the second source/drain area face each other with the second contact area interposed therebetween.
